(19) United States
(12) Patent Application Publication
(10) Pub. No.: US 2007/0211441 A1
(43) Pub. Date: Sep. 13, 2007

(54) Container for electronic components

(75) Inventor: Mun En Wang, Fountain Valley, CA (US)

Correspondence Address: CHARLES C.H. WU, 98 DISCOVERY, IRVINE, CA, 92618-3105, US

(73) Assignee: AMF TECHNOLOGY, INC.

(21) Appl. No.: 11/373,570

(22) Filed: Mar. 10, 2006

(51) Int. Cl. H05K 5/00

(52) U.S. Cl. 361/752

(57) ABSTRACT

An enclosure for securely place electronics therein uses fewer parts and with the parts being simple in structure. The part of enclosure can be easily and securely assembled. Further the enclosure can be easily disassembled.

### BACKGROUND OF THE INVENTION

1. Field of the Invention

The invention pertains to the field of container. More particularly, the invention pertains to improved container for electronic components. Yet more specifically, the invention pertains to improved container for ballasts with its associated electronics relating to a lighting device.

2. Description of Related Art

Enclosures for electronics are known. U.S. Pat. No. 4,903,167 to Lichtensperger discloses a casing for accommodating electronic components mounted on a printed circuit board, a lower box has a substantially U-shaped cross section, and includes a floor and at least two side walls. Each of the side walls has a horizontal slot proximate an upper edge thereof. At least one of the side walls has a resilient snap nose formed therein which is biased inwardly in the casing. A lid is also provided for closing the lower box, and the lid may have a closing edge thereon formed as a cross-sectionally double obtuse-angled stop tongue. A bead may be provided on a lower portion of the snap nose to orient a pc board in the casing.

U.S. Pat. No. 6,225,559 to Hubner et al discloses a heat transfer housing for a printed circuit board, which has an electrical component having a thermal contact area. The housing includes an extruded section having a contact area and contours for receiving the printed circuit board. One of the walls of the housing that is initially formed displaces outwardly through an angle. When the printed circuit board is installed in the housing, the outwardly displaced wall is rotated inwardly and held in place by a cover. The wall includes a portion which bears against the printed circuit board and forces the thermal contact area of the electrical component to bear against the contact area of the housing for efficient heat transfer.

U.S. Patent Application 20040184245 to Satoshi et al. discloses an electronic apparatus with a housing having one end, components contained in the housing, and a door which is lockable at a closed position to hide one end of the housing. The housing has a base to support the door, and a cover connected removable to the base. The cover is removed from the base by sliding toward the door, and hooked on the base by sliding away from the door. The door prevents the cover from sliding in the direction of separating the cover from the base, as long as being locked at the closed position.

The known containers for electronics tend to use a plurality of parts. Also, the parts tend to possess elaborate shapes or forms that are complicated and expensive to make. Therefore, there is a need to have an enclosure that uses fewer parts, which are simple in structure. Further there is a need to have an enclosure that can be easily and securely assembled. Still further there is a need to have an enclosure that can be easily disassembled.

### SUMMARY OF THE INVENTION

An enclosure that uses fewer parts that are simple in structure is provided.

An enclosure that can be easily and securely assembled is provided.

An enclosure that can be easily disassembled is provided.

An enclosure that can securely place electronics therein is provided.

An enclosure for electronic device is provided. The enclosure includes a top member forming substantially a top portion of the enclosure with a pair of opposing degreed banded sides; a base member having a bottom portion and a pair of opposing sides having edges disposed to engage and securely affix the top thereon; and a pair of side members rigidly affixed onto the combined top and bottom members.

An improved enclosure system for ballasts with its associated electronics relating to a lighting device has an enclosure for electronic device and a circuit board. The enclosure includes a top member forming substantially a top portion of the enclosure with a pair of opposing degreed banded sides; a base member having a bottom portion and a pair of opposing sides having edges disposed to engage and securely affix the top thereon; and a pair of side members rigidly affixed onto the combined top and bottom members. The circuit board is securely affixed onto a tacking element disposed to slidably receive and securely affix the circuit board thereon.

### BRIEF DESCRIPTION OF THE DRAWING

FIG. 1 shows a perspective view of the present invention.

FIG. 2 shows a blow up view of FIG. 1.

FIG. 3 shows a sectional or side view of the present invention.

FIG. 4 shows a side cover suitable for affixing onto either side of FIG. 1.

### DETAILED DESCRIPTION OF THE INVENTION

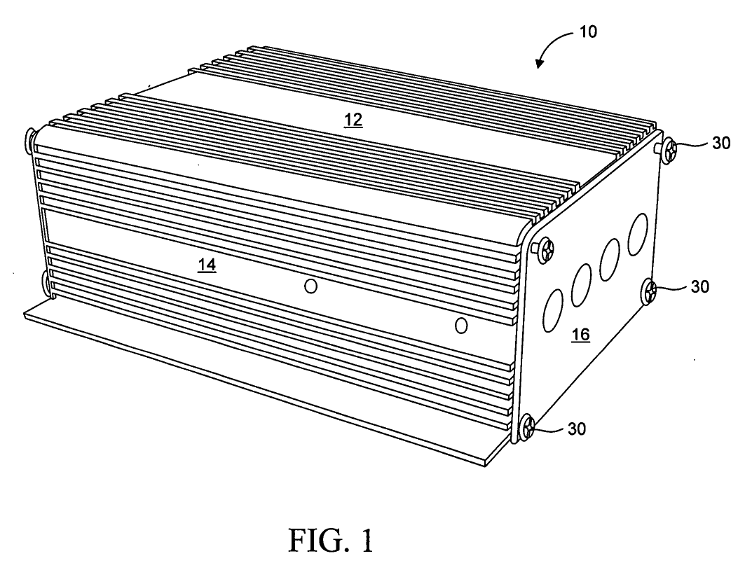

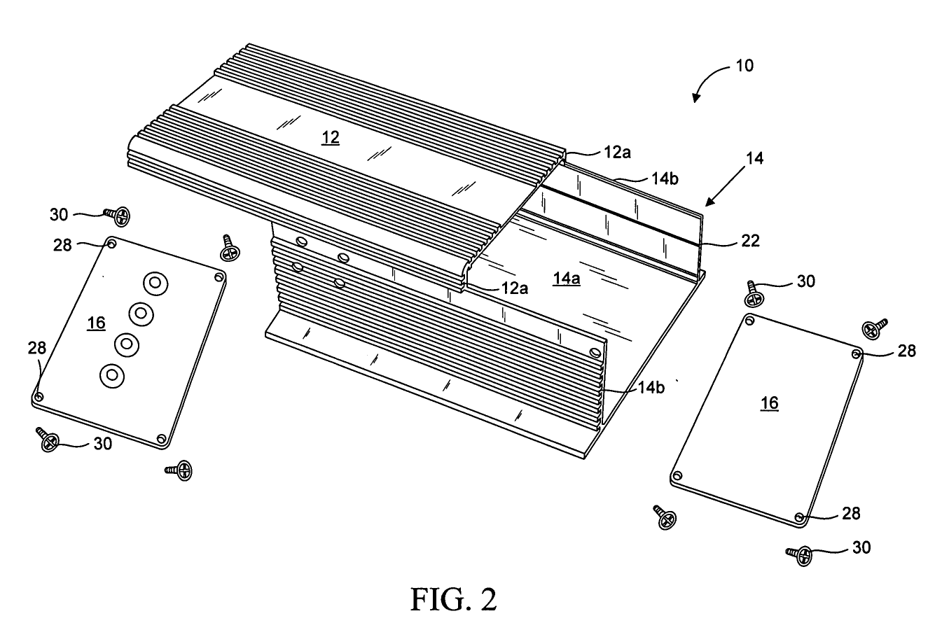

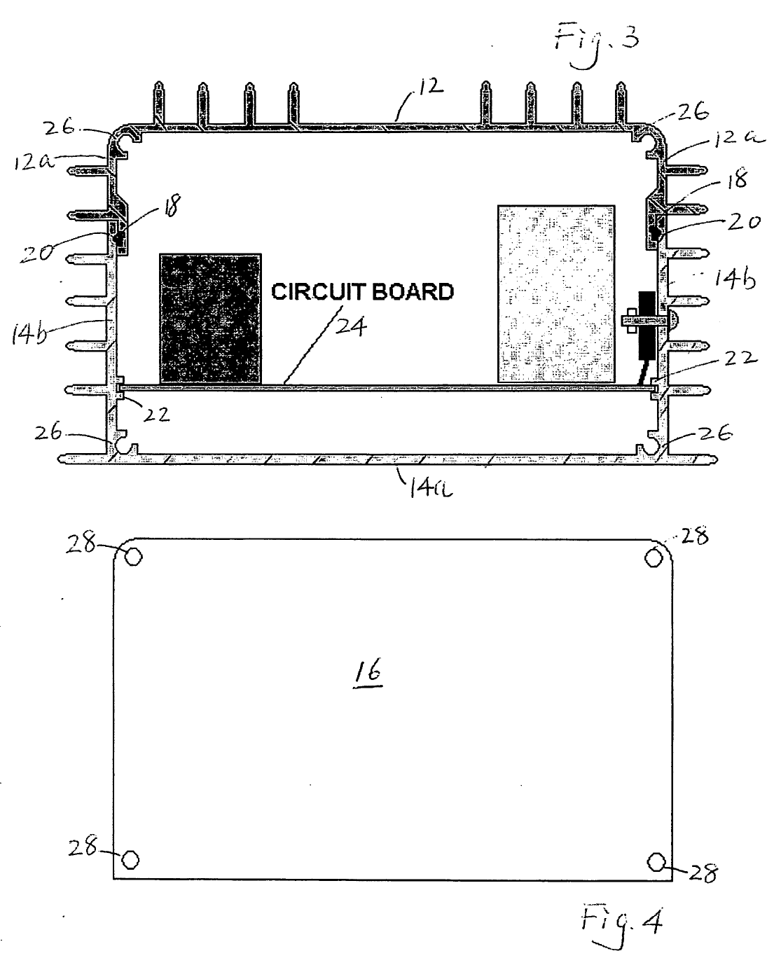

Referring to FIGS. 1-4, an enclosure 10 for ballasts relating to a light device with a cover 12 and a base 14 is provided. Base 14 is formed out of a single piece having a bottom member 14a and a pair of opposite perpendicular members 14b formed substantially perpendicular to bottom member 14a. On the inside of the perpendicular members 14b, a pair of notches 22 are formed for receiving a circuit board 24 having electronic component thereon. Notches 22 may be a single groove form on the entire length of the inside of the perpendicular members 14b, or alternatively only on selected locations along a pair of straight lines on the inside surface of perpendicular members 14b. On the outside of bottom member 14a, a pair flanges is formed or defined by the pair of opposite perpendicular members 14b. The flanges may be used to affix enclosure onto a third member.

Enclosure 10 relating to a lighting device further has a pair of side members 16 positioned opposite to each other, on the sides of enclosure 10 relating to a light device. Side member 16 is disposed to be rigidly affixed onto the unified whole of the cover 12 and base 14. The affixing of the unified whole is achieved by forming a tongue 18 substantially along the edges of the entire length of cover 12 and a corresponding groove 20 along the edges of base 14. Cover 12 may have a pair of flanges 12a bending with an angle or perpendicular to its main body having the edges for forming the tongue 18. On the outside surface of the unified whole, there may be grooves or protrusions for such purposes as heat dissipation.

At the corners of enclosure 10 relating to a light device, threaded receiving elements 26 are formed on the unified whole of both cover 12 and base 14. Matching holes 28 are interposed between 26 and fixing members such as screws 30 for letting screws 30 to rigidly affix side member 16 onto the other members of enclosure 10 relating to a light device, i.e. cover 12 and base 14.

As can be seen, the preferred embodiment of the present invention has only limited number of parts to achieved the unified whole of enclosure 10 relating to a light device. In other words, cover 12, base 14, a pair of side members 16 and eight screws 30 may be the only parts used to form enclosure 10 relating to a light device. Additionally a pre-assembled circuit board 24 having electronic elements thereon has a pair of opposing edges disposed to slide into the inside of the unified whole via groove or receiving track 22 formed on the inside surface of perpendicular members 14b.

To assemble the present invention, cover 12 is gently pressed against base 14 whereby the tongue of cover 12 is meshed or engaged into the groove of base 14. The two side members 16 are affixed onto the unified whole of cover 12 and base 14 by matching hole 28 of side member 16 with their corresponding receiving element 26 and using screws 30 for the resultant rigid affixation.

The parts of the present invention may be formed of metal such as aluminum. Cover 12 and base 14 may be formed by extrusion, injection molding, or other type of pressurized forming means using such melted metal as aluminum. Alternatively, cover 12 and base 14 may be formed by sintering using powder metal.

In an alternate embodiment, cover 12 may have the grooves and base 14 the tongues. Additionally, circuit board 24 may have edges with sufficient elasticity to be securely fit or squeezed into groove 22. Through apertures may be formed on the parts of the present invention such as side 16 for letting such thing as electric wirings to pass therethrough.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. An enclosure for electronic device comprising:
a top member forming substantially a top portion of said enclosure with a pair of opposing degreed banded sides;
a base member having a bottom portion and a pair of opposing sides having edges disposed to engage and securely affix said top thereon; and
a pair of side members rigidly affixed onto the combined top and bottom members.

2. The enclosure of claim 1, wherein said top is securely affixed onto said base by having said edges of each of said pair of opposing sides of said base connect with each of said edges of said pair of opposing degreed banded sides respectively.

3. The enclosure of claim 1, wherein said edges of each of said pair of opposing sides of said base connects with each of said edges of said pair of opposing degreed banded sides respectively by having a tongue formed on one type of edges and a groove formed on the other type of edges, or vice versa.

4. The enclosure of claim 1, wherein each of said pair of opposing sides of said base member comprises semi-elastic material such that said bends sufficiently for said top member to securely engage said based member.

5. The enclosure of claim 1, wherein said bottom portion of said base member has a pair of opposing flanges with each of said pair of opposing flanges extending out of the confines of said pair of opposing sides.

6. The enclosure of claim 1, wherein said enclosure comprises metal.

7. The enclosure of claim 6, wherein said enclosure comprises sintered metal.

8. The enclosure of claim 6, wherein said enclosure comprises metal formed by injection molding.

9. An improved enclosure system for ballasts with its associated electronics relating to a lighting device comprising:
an enclosure for electronic device including:
a top member forming substantially a top portion of said enclosure with a pair of opposing degreed banded sides;
a base member having a bottom portion and a pair of opposing sides having edges disposed to engage and securely affix said top thereon; and
a pair of side members rigidly affixed onto the combined top and bottom members; and
a circuit board securely affixed onto a tacking element disposed to slidably receive and securely affix said circuit board thereon.

10. The system of claim 1, wherein said top is securely affixed onto said base by having said edges of each of said pair of opposing sides of said base connect with each of said edges of said pair of opposing degreed banded sides respectively.

11. The system of claim 1, wherein said edges of each of said pair of opposing sides of said base connects with each of said edges of said pair of opposing degreed banded sides respectively by having a tongue formed on one type of edges and a groove formed on the other type of edges, or vice versa.

12. The system of claim 1, wherein each of said pair of opposing sides of said base member comprises semi-elastic material such that said bends sufficiently for said top member to securely engage said based member.

13. The system of claim 1, wherein said bottom portion of said base member has a pair of opposing flanges with each of said pair of opposing flanges extending out of the confines of said pair of opposing sides.

14. The system of claim 1, wherein said enclosure comprises metal.

15. The system of claim 14, wherein said enclosure comprises sintered metal. 14. The system of claim 1, wherein said enclosure comprises metal.

16. The system of claim 14, wherein said enclosure comprises metal formed by injection molding.
